(19) United States
(12) Patent Application Publication
(10) Pub. No.: US 2024/0175930 A1
(43) Pub. Date: May 30, 2024

(54) METHOD AND SYSTEM FOR DETERMINING STATE OF CHARGE, AND BATTERY SYSTEM

(71) Applicant: SAMSUNG SDI CO., LTD., Yongin-si (KR)

(72) Inventor: Sangmin HA, Yongin-si (KR)

(21) Appl. No.: 18/381,266

(22) Filed: Oct. 18, 2023

(30) Foreign Application Priority Data
Nov. 28, 2022 (KR) 10-2022-0161766

(51) Int. Cl. G01R 31/3835; G01R 31/396; H01M 10/42; H01M 10/48

(52) U.S. Cl. CPC G01R 31/3835; G01R 31/396; H01M 10/4257; H01M 10/482; H01M 2010/4271

(57) ABSTRACT

A method for determining a state of charge of a battery system, including calculating a voltage difference between a first voltage detected at a first time point and a second voltage detected at a second time point, for each of a plurality of cells included in a battery module, selecting a representative cell having a maximum voltage difference among the plurality of cells, and estimating a state of charge of the battery module by using a representative cell voltage of the representative cell.

### CROSS-REFERENCE TO RELATED APPLICATION

Korean Patent Application No. 10-2022-0161766 filed in the Korean Intellectual Property Office on Nov. 28, 2022, is incorporated herein by reference in its entirety.

### BACKGROUND

### 1. Field

A method for determining a state of charge, and a battery system is disclosed.

### 2. Description of the Related Art

An energy storage system (ESS) is a system that increases energy use efficiency by storing a large amount of electrical energy and supplying the stored electrical energy when electrical energy is needed.

### SUMMARY

Embodiments are directed to a method for determining a state of charge of a battery system, including calculating a voltage difference between a first voltage detected at a first time point and a second voltage detected at a second time point, for each of a plurality of cells included in a battery module, selecting a representative cell having a maximum voltage difference among the plurality of cells, and estimating a state of charge of the battery module by using a representative cell voltage of the representative cell.

The first time point may be a time point at which a direction of a current flow of the battery module is changed from a charging direction to a discharging direction.

The first time point may be, while a direction of a current flow of the battery module is sequentially changed from a charging direction via a no-current state to a discharging direction, a time point at which the direction of the current flow is changed from the charging direction to the no-current state.

The first time point may be, while a direction of a current flow of the battery module is sequentially changed from a charging direction via a no-current state to a discharging direction, a time point at which the direction of the current flow is changed from the no-current state to the discharging direction.

The second time point may be a time point at which a direction of a current flow of the battery module is changed from a discharging direction to a charging direction.

The second time point may be, while a direction of a current flow of the battery module is sequentially changed from a discharging direction via a no-current state to a charging direction, a time point at which the direction of the current flow is changed from the discharging direction to the no-current state.

The second time point may be, while a direction of a current flow of the battery module is sequentially changed from a discharging direction via a no-current state to a charging direction, a time point at which the direction of the current flow is changed from the no-current state to the charging direction.

Embodiments are directed to an apparatus for determining a state of charge of a battery system, including a detection device detecting a voltage of each of a plurality of cells included in a battery module, and a battery management system calculating a voltage difference between a first voltage detected at a first time point and a second voltage detected at a second time point for each in the plurality of cells, selecting a cell having a maximum voltage difference among the plurality of cells as a representative cell, and estimating a state of charge of the battery module using a cell voltage of the representative cell.

The battery management system may determine a time point at which a direction of a current flow of the battery module is changed from a charging direction to a discharging direction as the first time point.

The battery management system may determine, while a direction of a current flow of the battery module is sequentially changed from a charging direction via a no-current state to a discharging direction, a time point at which the direction of the current flow is changed from the charging direction to the no-current state, as the first time point.

The battery management system may determine, while a direction of a current flow of the battery module is sequentially changed from a charging direction via a no-current state to a discharging direction, a time point at which the direction of the current flow is changed from the no-current state to the discharging direction as the first time point.

The battery management system may determine a time point at which a direction of a current flow of the battery module is changed from a discharging direction to a charging direction as the second time point.

The battery management system may determine, while a direction of a current flow of the battery module is sequentially changed from a discharging direction via a no-current state to a charging direction, a time point at which the direction of the current flow is changed from the discharging direction to the no-current state, or a time point at which the direction of the current flow is changed from the no-current state to the discharging direction as the second time point.

Embodiments are directed to a method for determining a state of charge of a battery system, including calculating a voltage difference between a first voltage detected at a first time point and a second voltage detected at a second time point, for each of a plurality of cells included in a battery module, selecting a representative cell having a maximum voltage difference among the plurality of cells, estimating a state of charge of the battery module by using a representative cell voltage of the representative cell, and performing a control function or a protection function based on the estimated state of charge of the battery module.

The first time point may be a time point at which a direction of a current flow of the battery module is changed from a charging direction to a discharging direction.

The first time point may be, while a direction of a current flow of the battery module is sequentially changed from a charging direction via a no-current state to a discharging direction, a time point at which the direction of the current flow is changed from the charging direction to the no-current state.

The first time point may be, while a direction of a current flow of the battery module is sequentially changed from a charging direction via a no-current state to a discharging direction, a time point at which the direction of the current flow is changed from the no-current state to the discharging direction.

The second time point may be a time point at which a direction of a current flow of the battery module is changed from a discharging direction to a charging direction.

The second time point may be, while a direction of a current flow of the battery module is sequentially changed from a discharging direction via a no-current state to a charging direction, a time point at which the direction of the current flow is changed from the discharging direction to the no-current state.

The second time point may be, while a direction of a current flow of the battery module is sequentially changed from a discharging direction via a no-current state to a charging direction, a time point at which the direction of the current flow is changed from the no-current state to the charging direction.

### BRIEF DESCRIPTION OF THE DRAWINGS

Features will become apparent to those of skill in the art by describing in detail exemplary embodiments with reference to the attached drawings in which:

FIG. 1 shows a battery system including a battery module, a detection device, and a battery management system according to an example embodiment.

FIG. 2 shows a graph of a method for detecting an inflection point in a battery system according to an example embodiment.

FIG. 3 shows a method for determining a state of charge in a battery system according to an example embodiment.

FIG. 4 shows an effect of a method for determining a state of charge according to an example embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

Hence, for the purpose of complete understanding of the aspects and the characteristics of the example embodiments, processes, factors, and skills that may not be needed by a person of ordinary skill in the art may not be described. In the drawings, relative sizes of elements, layers, and regions may be exaggerated for clarity.

In the present specification, the term “and/or” includes all or random combinations of a plurality of items that are related and listed. In example embodiments, the use of “can” or “may” signifies at least one embodiment. A singular term may include a plural form unless stated in another way.

Terms including ordinal numbers such as “first”, “second”, and the like will be used only to describe various components and are not to be interpreted as limiting these components. The terms are only used to differentiate one component from other components. In an implementation, a first constituent element could be termed a second constituent element, and similarly, a second constituent element could be termed a first constituent element.

It will be understood that when a constituent element or layer is referred to as being “on,” “connected to,” or “coupled to” another constituent element or layer, it can be directly on, connected to, or coupled to the other constituent element or layer, or one or more intervening constituent elements or layers may be present. In addition, it will also be understood that when a constituent element or layer is referred to as being “between” two constituent elements or layers, it can be the only constituent element or layer between the two constituent elements or layers, or one or more intervening constituent elements or layers may also be present.

Electrically connecting two constituent elements may include directly connecting two constituent elements and connecting the same with another constituent element therebetween. Another constituent elements may include a switch, a resistor, and a capacitor. When the embodiments are described, an expression of connection signifies electrical connection when an expression of direct connection is not provided.

Hereinafter, a method for determining a state of charge, a system for determining a state of charge performing the same, and a battery system according to an embodiment is described in detail with reference to the drawings.

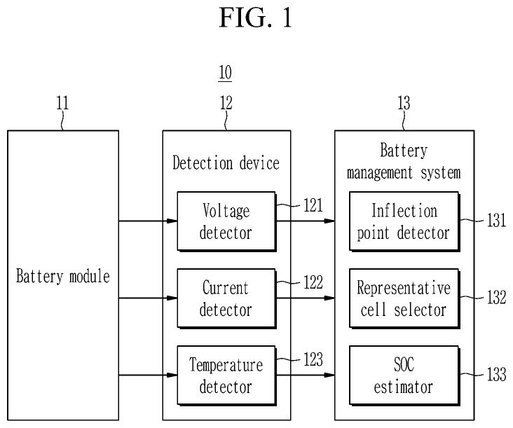

FIG. 1 shows a battery system including a battery module, a detection device, and a battery management system according to an example embodiment. Referring to FIG. 1, a battery system according to an embodiment 10 may include a battery module 11, a detection device 12, and battery management system (BMS) 13. The battery module 11 may include a plurality of cells that may be interconnected in series.

The detection device 12 may detect states of cells included in the battery module 11. The detection device 12 may include a voltage detector 121 configured to detect a cell voltage of each cell, or a module voltage of the battery module 11. The detection device 12 may further include a current detector 122 configured to detect current flowing through the battery module 11. The detection device 12 may further include a temperature detector 123 configured to detect a temperature of the battery module 11 for at least one location. As used herein, the term “or” is not an exclusive term, e.g., “A or B” would include A, B, or A and B.

A battery management system 13 may receive state information (voltage, current, temperature) of the battery module 11 from the detection device 12. The battery management system 13 may monitor a state (e.g., voltage, current, temperature, the state of charge (SOC), or a state of health (SOH)) of the battery module 11 based on state information received from the detection device 12. In addition, the battery management system 13 may perform a control function (e.g., temperature control, cell balancing control, or charge and discharge control), or a protection function (e.g., over-discharge, over-charge, or overcurrent prevention) based on a state monitoring result.

The battery management system 13 may function as an apparatus for determining a state of charge of the battery module 11, together with the detection device 12. Based on state information detected through the detection device 12, the battery management system 13 may select one of the cells included in the battery module 11 as a representative cell and estimate the state of charge of the battery module 11 by using a cell voltage of the selected representative cell. For this purpose, the battery management system 13 may include an inflection point detector 131, the representative cell selector 132, and a SOC estimator 133.

The inflection point detector 131 may detect a time point at which the battery module 11 shifts between charge and discharge as an inflection point, based on a charging or discharging state of the battery module 11. In an implementation, when a direction of a current flow of the battery module 11 is changed from charge direction to discharge direction via no-current, the inflection point detector 131 may detect a time point at which the direction of the current flow of the battery module 11 is changed from charge direction to no-current, or a time point at which the direction of the current flow of the battery module 11 is changed from no-current to discharge direction as the inflection point after charging.

In addition, e.g., when the direction of the current flow of the battery module 11 is changed from discharge direction to charge direction via no-current, the inflection point detector 131 may detect a time point at which the direction of the current flow of the battery module 11 is changed from discharge direction to no-current, or a time point at which the direction of the current flow of the battery module 11 is changed from no-current to charge direction as the inflection point after discharging. In addition, e.g., it is also possible that the inflection point detector 131 may detect the time point at which the direction of the current flow of the battery module 11 is changed from charge direction to discharge direction as the inflection point after charging, or may detect the time point at which the direction of the current flow of the battery module 11 is changed from discharge direction to charge direction as the inflection point after discharging.

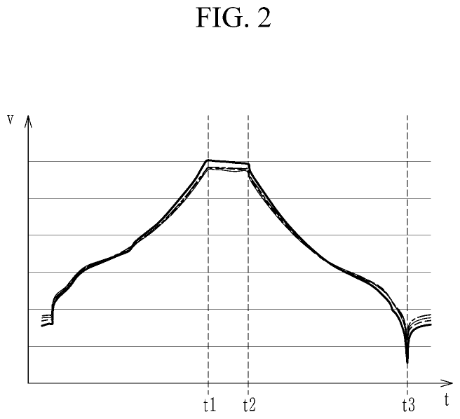

FIG. 2 shows a graph of a method for detecting an inflection point in a battery system according to an example embodiment. FIG. 2 illustrates voltage change trends of cells included in the battery module 11 as an example.

Referring to FIG. 2, the voltages of the cells included in the battery module 11 gradually increase by charging until a time point t1, and the charging of the battery module 11 is stopped from the time point t1 to a time point t2 (no-current state). Thereafter, the voltages of the cells included in the battery module 11 gradually decrease due to discharge from the time t2 to the time t3, and the charging of the battery module 11 starts again at the time t3. In this case, the inflection point detector 131 may determine the time point t1 at which the direction of the current state of the battery module 11 is changed from the charging direction to the no-current state, or the time point t2 at which the direction of the current state of the battery module 11 is changed from the no-current state to the discharging direction as the inflection point after charging, and may determine the time point t3 at which the direction of the current flow of the battery module 11 is changed from the discharging direction to the charging direction as the inflection point after discharging.

Referring to FIG. 1, when the inflection point is detected by the inflection point detector 131, the representative cell selector 132 may calculate a voltage difference between cell voltages detected at consecutive inflection points, with respect to each cell. In an implementation, the representative cell selector 132 may calculate, for each cell, a voltage difference between cell voltage detected at the inflection point after charging and a cell voltage detected at the inflection point after discharging afterwards. When the voltage difference between the inflection points is calculated for each cell, the representative cell selector 132 may select a cell having a largest voltage difference as the representative cell of the battery module 11. Cells may be charged and discharged faster than other cells as their capacity may be smaller, or their internal resistance may be larger. Therefore, since a cell having a larger cell voltage difference between the inflection point after charging and the inflection point after discharging may have a smaller capacity or a larger internal resistance, the cell with the largest voltage difference may be a cell with the smallest capacity or a cell with the largest resistance.

When the representative cell is selected among the battery module 11, the SOC estimator 133 may estimate the SOC of the battery module 11 by using current, or temperature of the battery module 11 together with the cell voltage of the representative cell detected through the detection device 12.

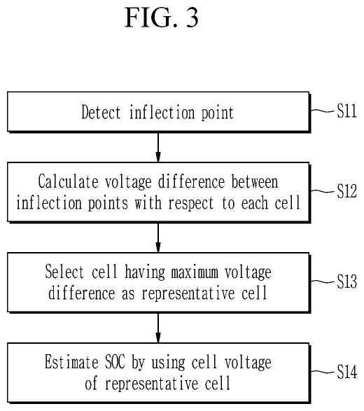

FIG. 3 shows a method for determining a state of charge in a battery system according to an example embodiment. The method of FIG. 3 may be performed by the battery management system described with reference to FIG. 1.

Referring to FIG. 3, at step S11, the battery management system 13 according to an embodiment may detect the inflection points. The inflection points may be time points at which the battery module 11 shifts between charge and discharge, based on the charging and discharging state of the battery module 11. At the step S11, the battery management system 13 may detect the time point at which the direction of the current flow of the battery module 11 may be changed from charge direction to discharge direction or the no-current state as the inflection point after charging. In addition, the battery management system 13 may detect the time point at which the direction of the current flow of the battery module 11 is changed from discharge direction to charge direction or the no-current state as the inflection point after discharging.

When the inflection points are detected through the step S11, the battery management system 13 may calculate the voltage difference between the inflection points with respect to each cell included in the battery module 11, at step S12. In an implementation, the battery management system 13 may calculate, for each cell, a voltage difference between cell voltage detected at the inflection point after charging and a cell voltage detected at the inflection point after discharging afterwards.

When the voltage difference between the inflection points for each cell is calculated through the step S12, the battery management system 13 may select the cell having the largest calculated voltage difference among the cells included in the battery module 11 as the representative cell of the battery module 11, at step S13.

The representative cell may be selected in step S13, where the battery management system 13 may estimate the SOC of the battery module 11 by using current or temperature of the battery module 11 together with the cell voltage of the representative cell at step S14. Such estimated SOC may be considered as the SOC of all cells included in the battery module 11, and thereafter used in performing the control function or the protection function of the battery module 11.

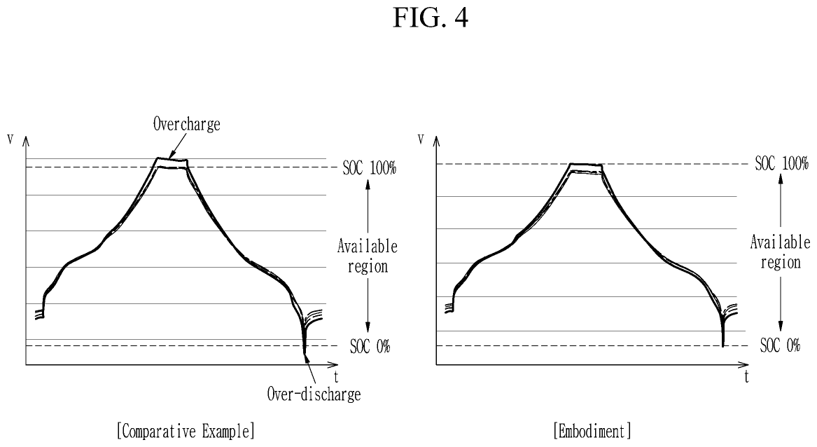

FIG. 4 shows an effect of a method for determining a state of charge according to an example embodiment. In FIG. 4, the diagram in the comparison example shows a voltage change trend obtained by estimating the SOC of the battery module 11 by using the average voltage of the cells included in the battery module 11, whereas the diagram in Embodiment section shows a voltage change trend obtained by estimating the SOC through the above-described method.

Referring to FIG. 4, in the case of the comparison example, cells may be over-charged or over-discharged out of the available region of the actual cell. In comparison, in the case of using a method for determining SOC according to an embodiment, all cells included in the battery module 11 may be charged and discharged within the available region.

As described above, a method for determining SOC according to an embodiment may protect the battery system from dangerous situations such as over-charge and over-discharge while decreasing the amount of calculation for calculating the SOC.

Electronic or electrical devices according to example embodiments and/or other related devices or constituent elements may be realized by using appropriate hardware, firmware (e.g., an application-specific integrated circuit), software, or combinations of software, firmware, and hardware. In an implementation, various configurations of the above-noted devices may be positioned on one integrated circuit (IC) chip or an individual IC chip. In addition, various configurations of the above-noted devices may be realized on a flexible printed circuit film, a tape carrier package (TCP), a printed circuit board (PCB), or one substrate. The electrical or mutual connections described in the present specification may, e.g., be realized by the PCB, wires on different types of circuit carriers, or conductive elements. The conductive elements may, e.g., include metallization such as surface metallizations and/or pins, and may include conductive polymers or ceramics.

In addition, the various configurations of the devices may be performed by at least one processor to perform the above-described various functions, they may be performed in at least one computing device, and they may be processes or threads for performing computer program instructions and interacting with other system constituent elements. The computer program instruction may be stored in a memory realizable in a computing device using a standard memory device such as a random access memory (RAM). The computer program instruction may also be stored in a non-transitory computer readable medium such as a CD-ROM or a flash drive.

Further, a person of ordinary skill in the art would understand that various functions of the computing device may be combined or united to a single computing device, or functions of a specific computing device may be dispersed to at least another computing device while not digressing from the range of the example embodiments.

By way of summation and review, an ESS may include a battery system, a battery management system (BMS) configured to manage the battery system, e.g., by monitoring voltage, current, or temperature, of the battery system, a power conversion system (PCS) configured to perform AC-DC conversion and distribution function, and an energy management system (EMS) configured to control an entire system of the ESS, e.g., by collecting and managing information on the state of the ESS as well as controlling energy flow of the ESS.

A battery system of the ESS may include a plurality of battery racks electrically interconnected to each other, and each battery rack may include dozens to hundreds of serially connected cells. Cells constituting one battery rack may have differences in deterioration degree and characteristics due to differences in manufacturing processes or operating environments (e.g., temperature). A method for determining a state of charge, a system for determining a state of charge performing the same, and a battery system capable of protecting a battery system from dangerous situations such as over-charge and over-discharge while decreasing the amount of calculation for calculating the SOC is disclosed.

When calculating the state of charge (SOC) for all cells constituting the battery rack to consider differences in the degree of deterioration and the characteristics, large-capacity memory and fast calculation speed are desired, which may not be easily applicable to embedded systems. To solve this problem, a method of calculating SOC using the average voltage of all cells constituting one battery rack as a representative value has been proposed. However, when SOC is calculated using the average voltage as a representative value, an error with the actual available capacity of the battery rack may occur, resulting in over-charging when fully charged and over-discharging when fully discharging. According to the present disclosure, the battery system may be protected from dangerous situations such as over-charge and over-discharge while decreasing the amount of calculation for calculating the SOC.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A method for determining a state of charge of a battery system, comprising:
calculating a voltage difference between a first voltage detected at a first time point and a second voltage detected at a second time point, for each of a plurality of cells included in a battery module;
selecting a representative cell having a maximum voltage difference among the plurality of cells; and
estimating a state of charge of the battery module by using a representative cell voltage of the representative cell.

2. The method as claimed in claim 1, wherein the first time point is a time point at which a direction of a current flow of the battery module is changed from a charging direction to a discharging direction.

3. The method as claimed in claim 1, wherein the first time point is, while a direction of a current flow of the battery module is sequentially changed from a charging direction via a no-current state to a discharging direction, a time point at which the direction of the current flow is changed from the charging direction to the no-current state.

4. The method as claimed in claim 1, wherein the first time point is, while a direction of a current flow of the battery module is sequentially changed from a charging direction via a no-current state to a discharging direction, a time point at which the direction of the current flow is changed from the no-current state to the discharging direction.

5. The method as claimed in claim 1, wherein the second time point is a time point at which a direction of a current flow of the battery module is changed from a discharging direction to a charging direction.

6. The method as claimed in claim 1, wherein the second time point is, while a direction of a current flow of the battery module is sequentially changed from a discharging direction via a no-current state to a charging direction, a time point at which the direction of the current flow is changed from the discharging direction to the no-current state.

7. The method as claimed in claim 1, wherein the second time point is, while a direction of a current flow of the battery module is sequentially changed from a discharging direction via a no-current state to a charging direction, a time point at which the direction of the current flow is changed from the no-current state to the charging direction.

8. An apparatus for determining a state of charge of a battery system, comprising:
a detection device detecting a voltage of each of a plurality of cells included in a battery module; and
a battery management system calculating a voltage difference between a first voltage detected at a first time point and a second voltage detected at a second time point for each in the plurality of cells, selecting a cell having a maximum voltage difference among the plurality of cells as a representative cell, and estimating a state of charge of the battery module using a cell voltage of the representative cell.

9. The apparatus as claimed in claim 8, wherein the battery management system determines a time point at which a direction of a current flow of the battery module is changed from a charging direction to a discharging direction as the first time point.

10. The apparatus as claimed in claim 8, wherein the battery management system determines, while a direction of a current flow of the battery module is sequentially changed from a charging direction via a no-current state to a discharging direction, a time point at which the direction of the current flow is changed from the charging direction to the no-current state, as the first time point.

11. The apparatus as claimed in claim 8, wherein the battery management system determines, while a direction of a current flow of the battery module is sequentially changed from a charging direction via a no-current state to a discharging direction, a time point at which the direction of the current flow is changed from the no-current state to the discharging direction as the first time point.

12. The apparatus as claimed in claim 8, wherein the battery management system determines a time point at which a direction of a current flow of the battery module is changed from a discharging direction to a charging direction as the second time point.

13. The apparatus as claimed in claim 8, wherein the battery management system determines, while a direction of a current flow of the battery module is sequentially changed from a discharging direction via a no-current state to a charging direction, a time point at which the direction of the current flow is changed from the discharging direction to the no-current state, or a time point at which the direction of the current flow is changed from the no-current state to the charging direction as the second time point.

14. A method for determining a state of charge of a battery system, comprising:
calculating a voltage difference between a first voltage detected at a first time point and a second voltage detected at a second time point, for each of a plurality of cells included in a battery module;
selecting a representative cell having a maximum voltage difference among the plurality of cells;
estimating a state of charge of the battery module by using a representative cell voltage of the representative cell; and
performing a control function or a protection function based on the estimated state of charge of the battery module.

15. The method as claimed in claim 14, wherein the first time point is a time point at which a direction of a current flow of the battery module is changed from a charging direction to a discharging direction.

16. The method as claimed in claim 14, wherein the first time point is, while a direction of a current flow of the battery module is sequentially changed from a charging direction via a no-current state to a discharging direction, a time point at which the direction of the current flow is changed from the charging direction to the no-current state.

17. The method as claimed in claim 14, wherein the first time point is, while a direction of a current flow of the battery module is sequentially changed from a charging direction via a no-current state to a discharging direction, a time point at which the direction of the current flow is changed from the no-current state to the discharging direction.

18. The method as claimed in claim 14, wherein the second time point is a time point at which a direction of a current flow of the battery module is changed from a discharging direction to a charging direction.

19. The method as claimed in claim 14, wherein the second time point is, while a direction of a current flow of the battery module is sequentially changed from a discharging direction via a no-current state to a charging direction, a time point at which the direction of the current flow is changed from the discharging direction to the no-current state.

20. The method as claimed in claim 14, wherein the second time point is, while a direction of a current flow of the battery module is sequentially changed from a discharging direction via a no-current state to a charging direction, a time point at which the direction of the current flow is changed from the no-current state to the charging direction.
